(19) United States
(12) Patent Application Publication
(10) Pub. No.: US 2020/0029450 A1
(43) Pub. Date: Jan. 23, 2020

(54) HOUSING AND ELECTRONIC DEVICE USING THE SAME

(71) Applicants: SHENZHEN FUTAIHONG PRECISION INDUSTRY CO., LTD., Shenzhen (CN); FIH (HONG KONG) LIMITED, Kowloon (HK)

(72) Inventors: YI XIONG, Shenzhen (CN); WEI DENG, Shenzhen (CN); KE-LONG WU, Shenzhen (CN); KUN-HUA CHEN, Kowloon (HK)

(21) Appl. No.: 16/194,215

(22) Filed: Nov. 16, 2018

(30) Foreign Application Priority Data
Jul. 18, 2018 (CN) 201821150133.7

(51) Int. Cl. H05K 5/02; H04B 1/3888; H05K 5/00; H05K 5/06

(52) U.S. Cl. CPC H05K 5/0204; H05K 5/06; H05K 5/0086; H04B 1/3888

(57) ABSTRACT

A light emitting diode package includes a light emitting diode chip, a light conversion layer covering the light emitting diode chip, a reflecting layer surrounding the light emitting diode chip. The light emitting chip has a light output top surface, a first electrode and a second electrode. The first electrode and the second electrode are opposite to the light output top surface. The light emitting diode package further includes a supporting layer made of metal material. The supporting layer is mounted on a bottom surface of the reflecting layer facing away from the light output top surface and surrounds the light emitting chip and the light conversion layer.

### FIELD

The subject matter herein generally relates to a housing and an electronic device using the housing.

### BACKGROUND

A plastic part and a metal part of a housing is usually combined to form a housing where the rubber-metal combination is enhanced by bar grooves with rubber or nano-holes. However, waterproof requirements for a 5G mobile phone cannot be met by bar grooves with rubber or nano-holes.

Therefore, there is room for improvement within the art.

### BRIEF DESCRIPTION OF THE DRAWINGS

Implementations of the present disclosure will now be described, by way of embodiments only, with reference to the attached figures.

FIG. 1 is a diagrammatic view of an embodiment of a housing.

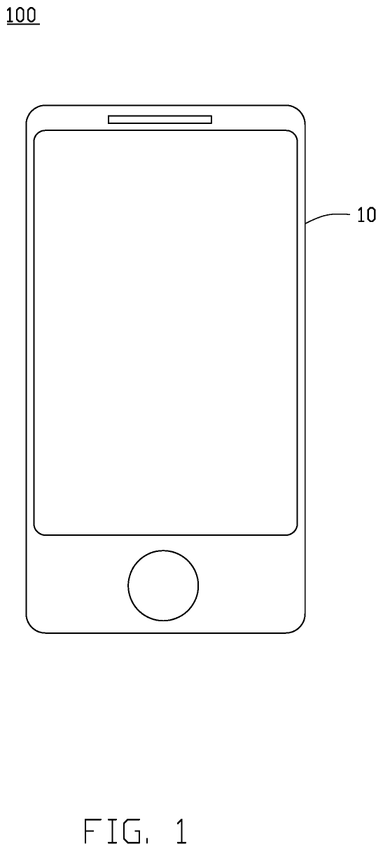

FIG. 2 is a diagrammatic view of an embodiment of an electronic device using the housing of FIG. 1.

FIG. 3 is a diagrammatic view of an embodiment of a metal part of the housing of FIG. 1.

FIG. 4 is an enlarged view of the metal part in circle III line of FIG. 3.

FIG. 5 is an enlarged view of another embodiment of a gripping structure of the housing.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

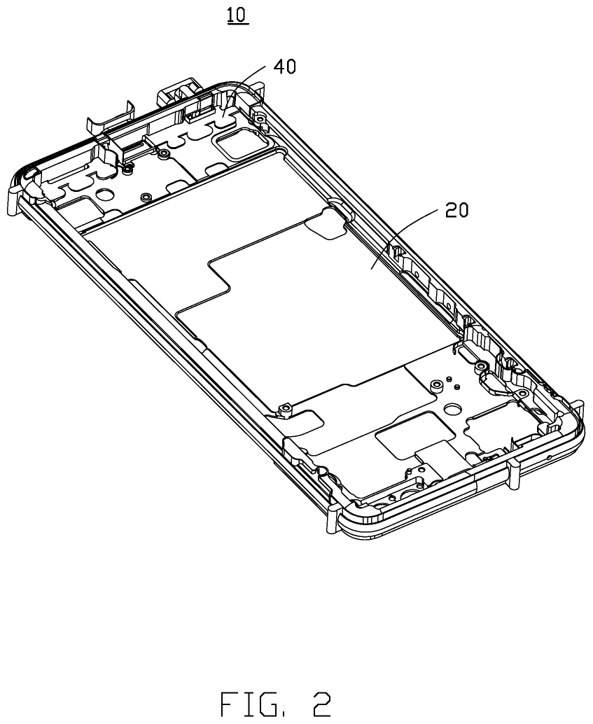

FIG. illustrates an embodiment of a housing 10. The housing 10 may be applied in an electronic device 100 (shown in FIG. 2), such as a mobile phone, a pad or a computer. In at least one embodiment, the electronic device 100 is a mobile phone.

The housing 10 comprises a metal part 20 and at least one plastic part 40. In another embodiment, the housing 10 may further comprise electronic elements, modules, circuits, or antennas to realize preset functions.

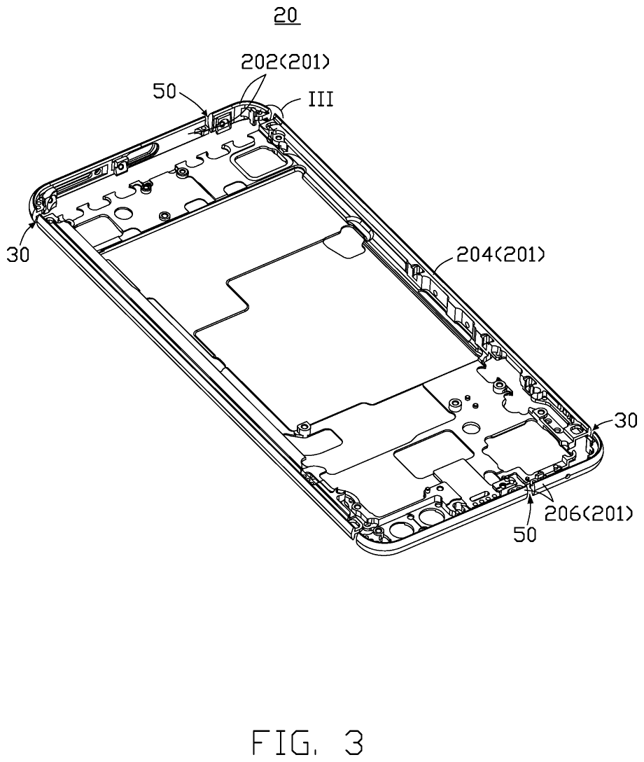

Referring to FIG. 3, the metal part 20 defines at least one partition groove 30. The at least one partition groove 30 divides the metal part 20 into at least two substrates 201. In at least one embodiment. The metal part 20 can be made of aluminum, magnesium, stainless steel, and other metal or alloy. The at least one partition groove 30 can reduce interferences with antenna signals caused by the housing 10.

In at least one embodiment, the metal part 20 comprises two partition grooves 30. The two partition grooves 30 divide the metal part 20 into three independent substrates 201. The three independent substrates 201 comprises a first substrate 202, a second substrate 204, and a third substrate 206. The second substrate 204 is located between the first substrate 202 and the third substrate 206.

At least one plastic part 40 each is received in one partition groove 30, and connects two of the substrates 201, thereby forming the housing 10. In at least one embodiment, each of the plastic part 40 can be made of at least one of polyphenylene sulfide, polybutylene terephthalate, polyamide, polyethylene terephthalate, polytrimethylene terephthalate, polyetherimide, polyetheretherketone and poly1,4-cyclohexylene dimethylene terephthalate.

In at least one embodiment, one of the plastic part 40 is received in the partition groove 30 between the first substrate 202 and the second substrate 204, and connects the first substrate 202 and the second substrate 204. Another one of the plastic part 40 is received in the partition groove 30 between the second substrate 204 and the third substrate 206, and connects the second substrate 204 and the third substrate 206. As result, the first substrate 202, the second substrate 204, and the third substrate 206 are connected by two of the plastic parts 40 to form the housing 10.

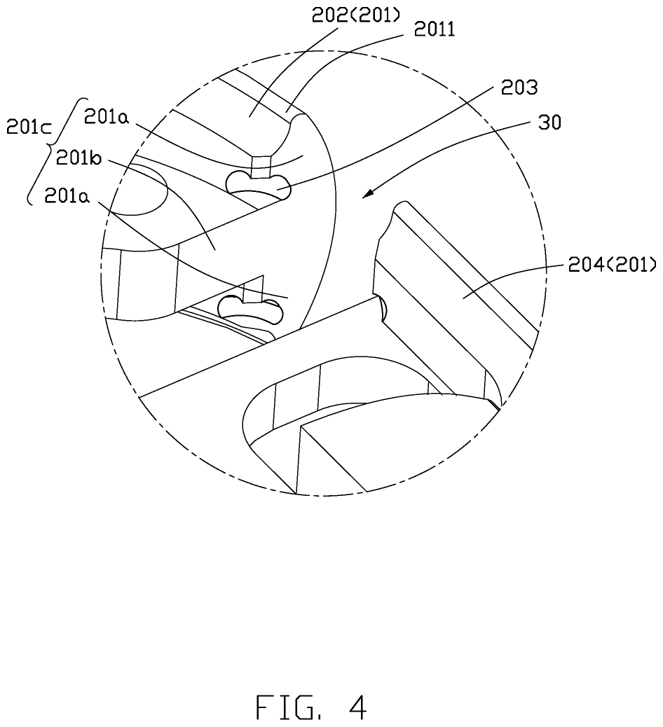

Referring to FIG. 4, each end portion 2011 of each of the substrate 201 is T-shaped, and comprises two first surfaces 201a and a second surface 201b between the two first surfaces 201a. The second surface 201b connects the two first surfaces 201a to form a T-shaped end surface 201c.

Each of the end portion 2011 of each of the substrate 201 further comprises at least one gripping structure 203. The plastic part 40 is embedded into the at least one gripping structure 203 to reinforce combination between the substrate 201 and the plastic part 40. In at least one embodiment, each gripping structure 203 is defined by inwardly recessing from a junction between the first surface 201a and the second surface 201b.

In at least one embodiment, each of the gripping structure 203 is an arcuate groove.

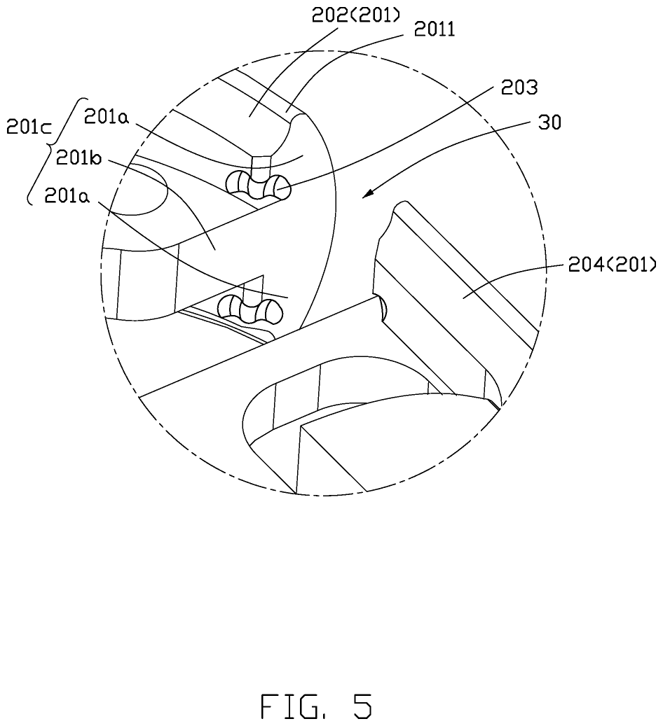

Referring to FIG. 5, each of the gripping structure 203 is wavy in another embodiment.

When the plastic parts 40 are formed between the first substrate 202 and the second substrate 204, and between the second substrate 204 and the third substrate 206, the plastic part 40 is embedded into the gripping structure 203 of the first substrate 202, the gripping structure 203 of the second substrate 204, the gripping structure 203 of the third substrate 206. Each of the plastic part 40 is bidirectionally embedded into the gripping structure 203, thereby reinforce combination between the substrate 201 and the plastic part 40, and make the device 100 waterproof.

Referring to FIG. 3, at least one partition portion 50 may be formed in the first substrate 202 and the third substrate 206, to reduce interference with antenna signals caused by the housing 10.

In at least one embodiment, each partition portion 50 is a plastic element.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A housing comprising:
a metal part comprising:
at least one partition groove;
wherein the at least one partition groove divides the metal part into at least two substrates, each end portion of each of the at least two substrates comprises at least one gripping structure; and
at least one plastic part;
wherein the at least one plastic part is connected to the at least two substrates of the metal part by each of the at least one plastic part being received in one of the at least one partition groove, and embedded into gripping structures.

2. The housing of claim 1, wherein each end portion of each of the at least two substrates is T-shaped.

3. The housing of claim 2, wherein each end portion of each of the at least two substrates further comprises two first surfaces and a second surface between the two first surfaces, the second surface connects to each of the two first surfaces to form a T-shaped end surface, each of the at least one gripping structure is formed on junctions between the two first surfaces and the second surface.

4. The housing of claim 3, wherein each of the at least one gripping structure is defined by inwardly recessing from junctions between the two first surfaces and the second surface.

5. The housing of claim 1, wherein each of the at least one gripping structure is an arcuate groove.

6. The housing of claim 1, wherein each of the at least one gripping structure is wavy.

7. The housing of claim 1, wherein at least one partition portion is formed in each of the at least two substrates.

8. The housing of claim 7, wherein the at least one partition portion is a plastic element.

9. An electronic device comprising:
a housing comprising:
a metal part comprising:
at least one partition groove;
wherein the at least one partition groove divides the metal part into at least two substrates, each end portion of each of the at least two substrates comprises at least one gripping structure; and
at least one plastic part;
wherein the at least one plastic part is connected to the at least two substrates of the metal part by each of the at least one plastic part being received in one of the at least one partition groove, and embedded into gripping structures.

10. The electronic device of claim 9, wherein each end portion of each of the at least two substrates is T-shaped.

11. The electronic device of claim 10, wherein each end portion of each of the at least two substrates further comprises two first surfaces and a second surface between the two first surfaces, the second surface connects each of the two first surfaces to form a T-shaped end surface, each of the at least one gripping structure is formed on junctions between the two first surfaces and the second surface.

12. The electronic device of claim 11, wherein each of the at least one gripping structure is defined by inwardly recessing from junctions between the first surfaces and the second surface.

13. The electronic device of claim 9, wherein each of the at least one gripping structure is an arcuate groove.

14. The electronic device of claim 9, wherein each of the at least one gripping structure is wavy.

15. The electronic device of claim 9, wherein at least one partition portion is formed in each of the at least two substrates.

16. The electronic device of claim 15, wherein the at least one partition portion is a plastic element.
